(19) United States
(12) Patent Application Publication
(10) Pub. No.: US 2017/0083736 A1
(43) Pub. Date: Mar. 23, 2017

(54) FINGERPRINT SENSING DEVICE AND METHOD FOR PRODUCING THE SAME

(71) Applicant: TONG HSING ELECTRONIC INDUSTRIES, LTD., Taipei City (TW)

(72) Inventors: Chien-Cheng WEI, Taipei City (TW); Zzu-Chi CHIU, Taipei City (TW)

(21) Appl. No.: 15/265,240

(22) Filed: Sep. 14, 2016

(30) Foreign Application Priority Data
Sep. 22, 2015 (TW) 104215290

(51) Int. Cl. G06K 9/00; H01L 31/18; H01L 31/14; H01L 25/00

(52) U.S. Cl. CPC G06K 9/0004; H01L 25/50; H01L 31/18; H01L 31/14; H01L 2225/06513

(57) ABSTRACT

A fingerprint sensing device includes an insulating package, an image-sensing element, a light-emitting element, and a conductive component. The insulating package has a top surface that is formed with a first recess and a second recess, and a bottom surface that is opposite to the top surface. The conductive component is formed in the insulating package and has opposite top and bottom ends that are respectively exposed from the top and bottom surfaces of the insulating package. The image-sensing element is electrically connected to the conductive component by flip-chip techniques and has a sensing region that is exposed from the first recess. The light-emitting element is electrically coupled to the conductive component.

### CROSS-REFERENCE TO RELATED APPLICATION

This application claims priority of Taiwanese Patent Application No. 104215290, filed on Sep. 22, 2015.

### FIELD

The disclosure relates to a fingerprint sensing device, more particularly to a capacitive fingerprint sensing device.

### BACKGROUND

Conventional fingerprint sensing devices may be classified into two major types, including optical fingerprint sensing devices and capacitive fingerprint sensing devices. The optical sensing devices may include a light source, a prism and an image-sensing element (e.g., a camera). When a user's fingertip is placed on the prism, the image-sensing element is able to capture the fingerprint image by taking into account the varying luminous intensity of light reflected from the ridges and valleys of the fingertip. However, inclusion of the prism causes conventional optical fingerprint sensing devices to be relatively bulky in size and have limited applicability in handheld electronic devices. In the case of conventional capacitive fingerprint sensing devices, generation of the user's fingerprint image usually involves the inclusion of high-density capacitive or pressure sensors that detect charge variations between ridges and valleys of the fingertip. Although the conventional capacitive fingerprint sensing devices are relatively compact in size, the production cost is relatively high and the image resolution is relatively low.

### SUMMARY

According to one aspect of the present disclosure, a fingerprint sensing device is provided. Such a fingerprint sensing device may include an insulating package, an image-sensing element, a light-emitting element, and a conductive component. The insulating package may have a top surface that is formed with a first recess and a second recess, and a bottom surface that is opposite to the top surface. The conductive component may be formed in the insulating package and have opposite top and bottom ends that are respectively exposed from the top and bottom surfaces of the insulating package. The image-sensing element may be electrically connected to the conductive component by flip-chip techniques and have a sensing region that is exposed from the first recess. The light-emitting element may be electrically coupled to the conductive component.

According to another aspect of the present disclosure, a method for producing a fingerprint sensing device is provided. Such a method may include steps of: providing a supporting component which includes a positioning element having a positioning surface, and a top circuit pattern layer positioned on the positioning surface; connecting an image-sensing element onto the top circuit pattern layer such that the image-sensing element is electrically coupled to the top circuit pattern layer, followed by attaching a light-emitting element onto the positioning surface; forming a plurality of conductive elements each being electrically coupled to the top circuit pattern layer, and forming a connecting unit electrically interconnecting the top circuit pattern layer and the light-emitting element; forming an insulating package to encapsulate the top circuit pattern layer, the image-sensing element, the conductive elements and the connecting unit, wherein the insulating package has a top surface connected to the positioning surface of the positioning element and a bottom surface opposite to the top surface; and removing the positioning element from the insulating package so as to expose the top circuit pattern layer, the image-sensing element and the light-emitting element from the top surface of the insulating package.

According to yet another aspect of the present disclosure, a method for producing a fingerprint sensing device is provided. Such a method may include steps of: providing a supporting component which includes a positioning element having a positioning surface, and a top circuit pattern layer positioned on the positioning surface; connecting an image-sensing element onto the top circuit pattern layer such that the image-sensing element is electrically connected to the top circuit pattern layer, followed by attaching a light-emitting element onto the positioning surface; forming a connecting unit to electrically interconnect the top circuit pattern layer and the light-emitting element; forming an insulating package to encapsulate the top circuit pattern layer, the image-sensing element, and the connecting unit, wherein the insulating package has a top surface connected to the positioning surface of the positioning element and a bottom surface opposite to the top surface; forming a plurality of holes each extending from the bottom surface of the insulating package to the top circuit pattern layer and each being defined by a surrounding surface; forming conductive elements respectively in the holes such that the conductive elements are electrically coupled to the top circuit pattern layer, wherein each of the conductive elements is formed on the surrounding surface by electroplating; and removing the positioning element from the insulating package so as to expose the top circuit pattern layer, the image-sensing element and the light-emitting element from the top surface of the insulating package.

### BRIEF DESCRIPTION OF THE DRAWINGS

Other features and advantages of the disclosure will become apparent in the following detailed description of the embodiments with reference to the accompanying drawings, of which:

FIG. 1 is a top plan view of a first exemplary embodiment of a fingerprint sensing device according to the present disclosure;

FIG. 2 is a flow chart of the first exemplary embodiment, illustrating a method for producing the fingerprint sensing device;

FIGS. 3 and 4 respectively are a top plan view and a sectional view of the first exemplary embodiment, illustrating a step of providing a supporting component;

FIG. 5 is a flow chart of the first exemplary embodiment, illustrating that a step of connecting an image-sensing element and light-emitting elements to the supporting component may include sub-steps;

FIGS. 6 to 8 respectively are a bottom plan view, a top plan view, and a sectional view of the first exemplary embodiment, illustrating a sub-step for connecting the image-sensing element and the light-emitting elements to the supporting component;

FIGS. 9 and 10 respectively are a top plan view and a sectional view of the first exemplary embodiment, illustrating another sub-step for connecting the image-sensing element and the light-emitting elements to the supporting component;

FIGS. 11 and 12 respectively are a top plan view and a sectional view of the first exemplary embodiment, illustrating a step of forming conductive elements;

FIG. 13 is a flow chart of the first exemplary embodiment, illustrating that a step of forming an insulating package may include sub-steps;

FIG. 14 is a sectional view of the first exemplary embodiment, illustrating one sub-step for forming the insulating package;

FIG. 15 is a sectional view of the first exemplary embodiment, illustrating another sub-step for forming the insulating package;

FIGS. 16 and 17 respectively are a top plan view and a sectional view of the first exemplary embodiment, illustrating a step of forming a bottom circuit pattern layer;

FIG. 18 is a sectional view of the first exemplary embodiment, illustrating a step of removing the positioning element from the insulating package;

FIG. 19 is a sectional view of the first exemplary embodiment, illustrating a step of rotating the insulating package such that the top surface faces upward;

FIG. 20 is a sectional view of the first exemplary embodiment, illustrating a step of forming a light-transmissive protecting layer;

FIG. 21 is a sectional view of the first exemplary embodiment of the fingerprint sensing device;

FIG. 22 is a sectional view of a second exemplary embodiment according to the present disclosure, illustrating that the conductive elements abut against a top die of a mold during the step of forming the insulating package;

FIG. 23 is a fragmentary sectional view of a third exemplary embodiment according to the present disclosure, illustrating the configuration of the conductive elements;

FIG. 24 is a fragmentary sectional view of a fourth exemplary embodiment according to the present disclosure, illustrating the configuration of the conductive elements;

FIG. 25 is a flow chart of a fifth exemplary embodiment of the method for producing the fingerprint sensing device according to the present disclosure; and

FIG. 26 is a fragmentary sectional view of the fifth exemplary embodiment, illustrating the configuration of the conductive elements.

### DETAILED DESCRIPTION

Before the disclosure is described in greater detail, it should be noted that like elements are denoted by the same reference numerals throughout the disclosure.

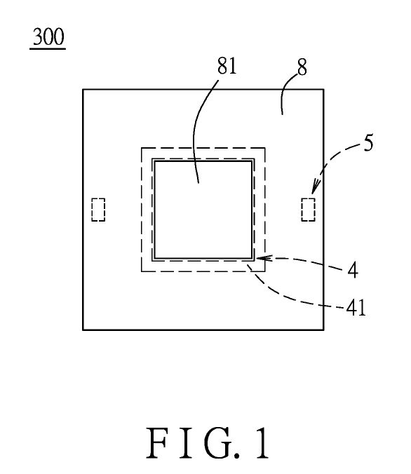

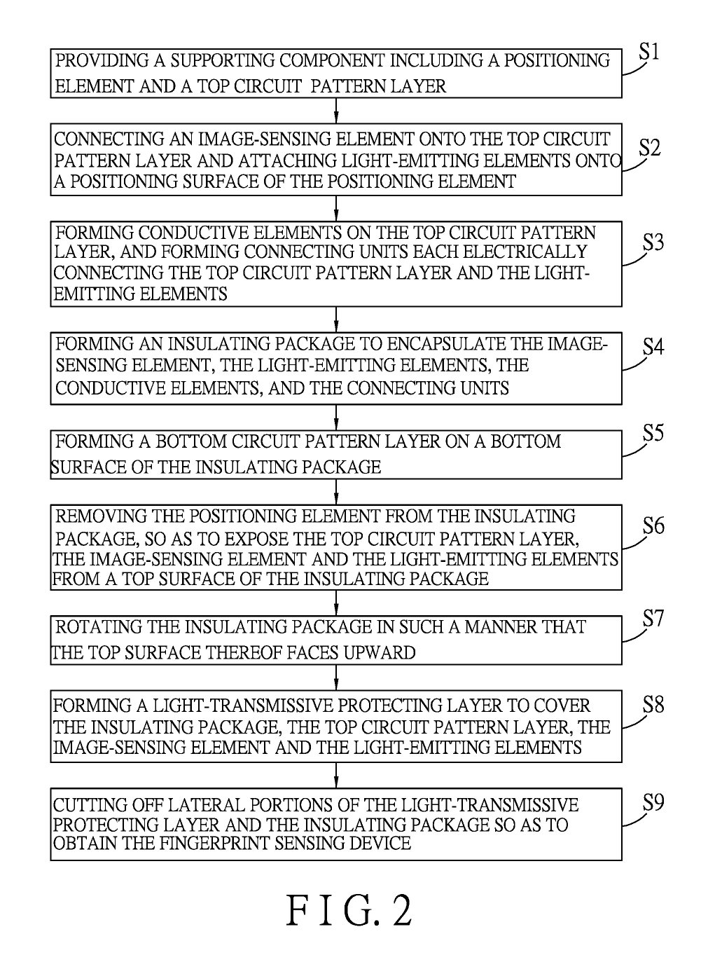

Referring to FIGS. 1 and 2, the first exemplary embodiment of a method for producing a fingerprint sensing device 300 as shown in FIG. 1 may include steps as illustrated in FIG. 2. The steps in FIG. 2 are described below.

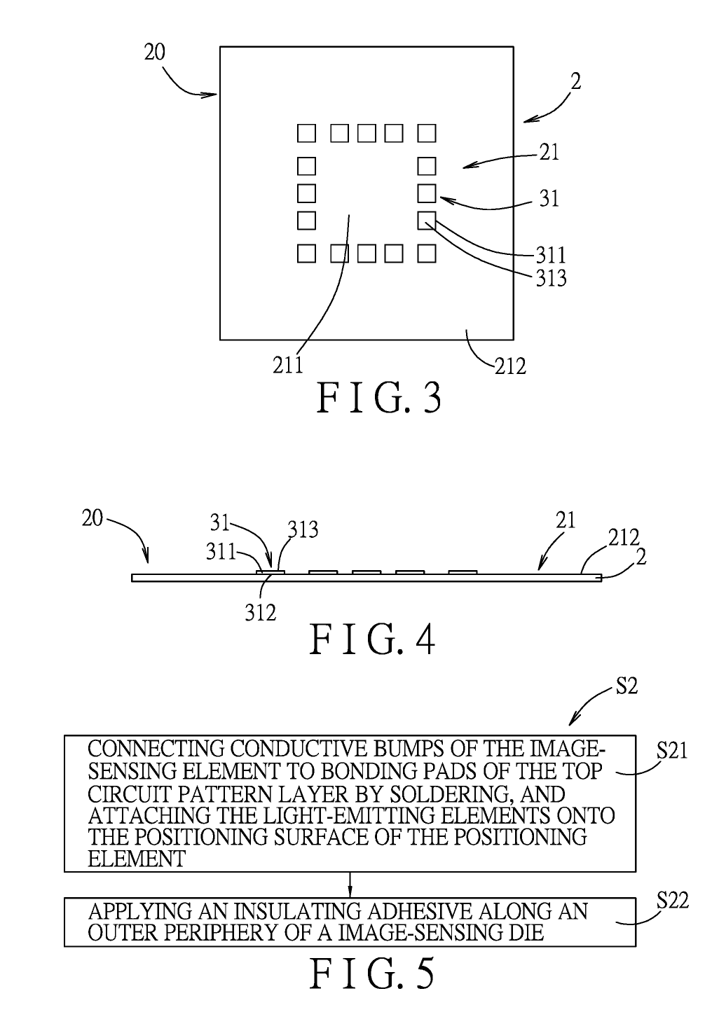

Step S1: providing a supporting component 20 as illustrated in FIGS. 2 to 4. The supporting component 20 may include a positioning element 2 having a positioning surface 21, and a top circuit pattern layer 31 positioned on the positioning surface 21. In certain embodiments, the positioning element 2 may be configured to have a quadrilateral shape as illustrated in FIG. 3. In certain embodiments, the top circuit pattern layer 31 may include a plurality of mutually spaced-apart first bonding pads 311. In such embodiments, the first bonding pads 311 may be arranged to define the positioning surface 21 into a central region 211 which is surrounded by the first bonding pads 311, and an outer surrounding region 212 surrounding the central region 211 as illustrated in FIG. 3. Each of the first bonding pads 311 may have an outer end surface 312 (see FIG. 4) that is connected to the positioning surface 21 of the positioning element 2, and a connecting surface 313 that is opposite to the outer end surface 312. In certain embodiments, the positioning element 2 may be a tape, and the positioning surface 21 may be an adhesive plane.

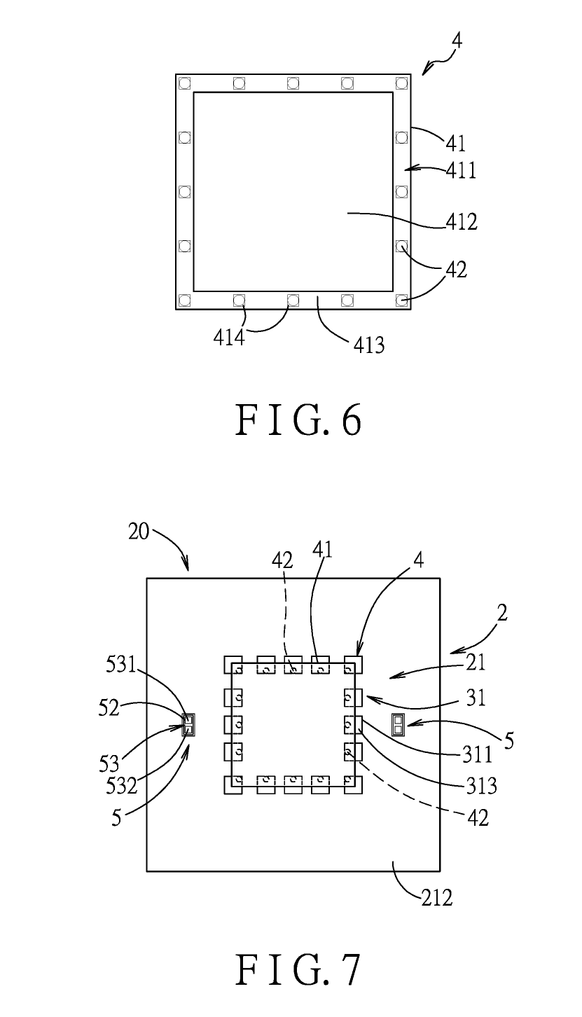

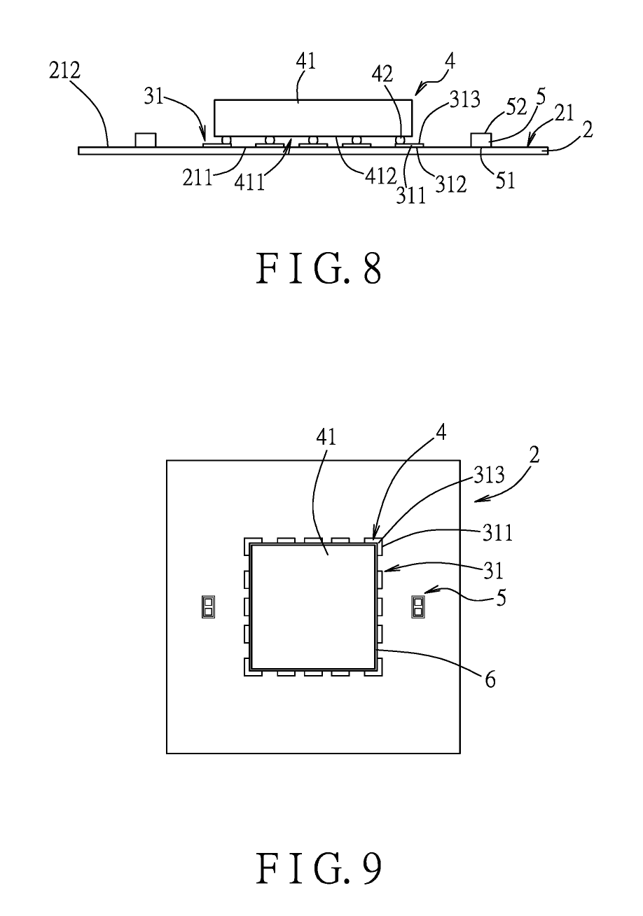

Step S2: connecting an image-sensing element 4 onto the top circuit pattern layer 31 such that the image-sensing element 4 is electrically coupled to the top circuit pattern layer 31, followed by attaching a plurality of light-emitting elements 5 onto the outer surrounding region 212 of the positioning surface 21 as illustrated in FIGS. 5 to 8. The image-sensing element 4 may be connected to the top circuit pattern layer 31 by flip-chip techniques. In certain embodiments, the image-sensing element 4 may include an image-sensing die 41, and a plurality of conductive bumps 42 formed on the image-sensing die 41 as illustrated in FIGS. 6 to 8. In such embodiments, the image-sensing die 41 may be a CMOS die and have an outer surface 411 having a sensing region 412, and a connecting region 413 that surrounds the sensing region 412 and that provides the conductive bumps 42 as illustrated in FIG. 6. In certain embodiments, each of the light-emitting elements 5 may be a sapphire-based LED and have an outer surface 51 that is attached to the positioning surface 21, an inner surface 52 that is opposite to the outer surface 51, and an electrode unit 53 that is disposed on the inner surface 52 and that includes first and second electrodes 531, 532 as illustrated in FIG. 7.

As shown in FIG. 5, in certain embodiments, Step S2 may include sub-Steps S21 and S22.

sub-Step S21: connecting each of the conductive bumps 42 of the image-sensing element 4 to the connecting surface 313 of a corresponding one of the first bonding pads 311 by soldering, such that the image-sensing die 41 is positioned at the central region 211 of the positioning surface 21, followed by attaching the outer surface 51 of each of the light-emitting elements 5 onto the outer surrounding region 212 of the positioning surface so as to surround the image-sensing element 4 as shown in FIG. 6. It may be noted that, the number of the light-emitting elements 5 can be adjusted based on actual demands and is not limited to what is disclosed in this embodiment, e.g., to include one single light-emitting element 5 may also suffice according to the present disclosure.

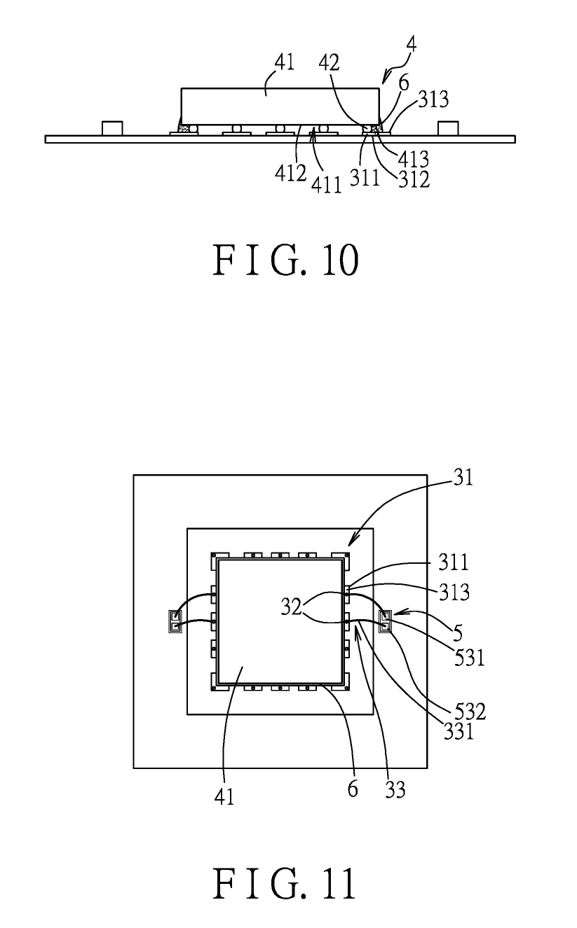

sub-Step S22: applying an insulating adhesive 6 along an outer periphery of the image-sensing die 41 to fill gaps between the connecting region 413 and the first bonding pads 311 and between the positioning surface 21 and the connecting region 413, as well as to enclose the conductive bumps 42 as illustrated in FIGS. 9 and 10. The insulating adhesive 6 may be a thermo-curable insulating adhesive and may fully isolate the sensing region 412 of the image-sensing die 41 from the external environment after being cured.

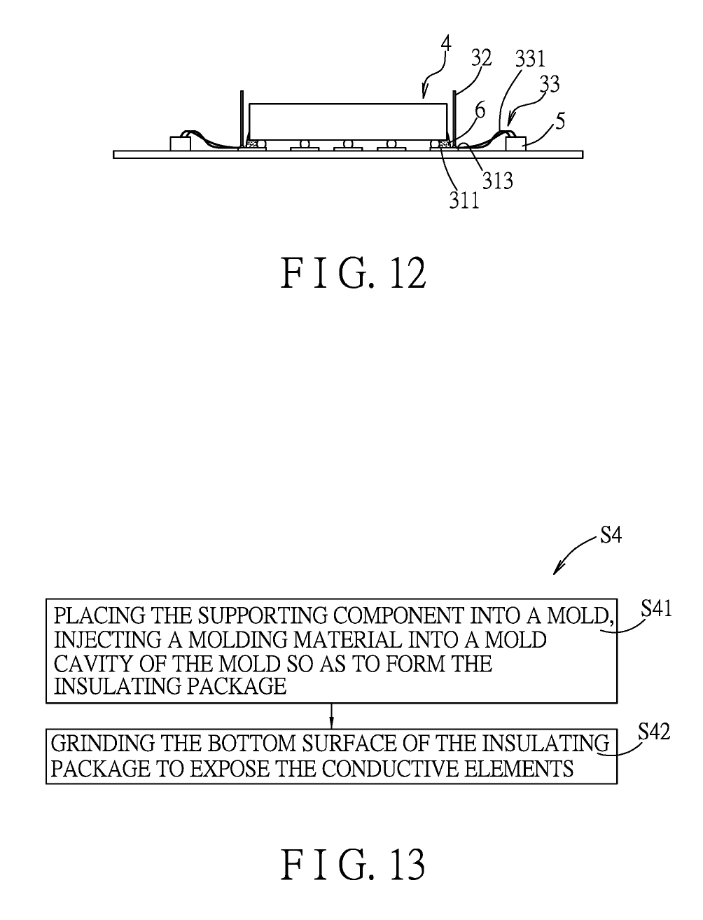

Step S3: forming a plurality of conductive elements 32 on the top circuit pattern layer 31, and forming a plurality of connecting units 33 each electrically interconnecting the top circuit pattern layer 31 and the electrode unit 53 of a corresponding one of the light-emitting elements 5 as illustrated in FIGS. 11 and 12. In certain embodiments, each of the conductive elements 32 may be configured as a metal wire that is formed on and perpendicular to the connecting surface 313 of a corresponding one of the first bonding pads 311. The conductive elements 32 may have a diameter of, e.g., 50 μm. The step of forming the conductive elements 32 may be conducted using a wire-bonding machine. In certain embodiments, each of the connecting units 33 may include a pair of connecting wires 331, each having one end electrically connected to one of the first and second electrodes 531, 532 of the corresponding one of the light-emitting elements 5, and the other end electrically connected to the connecting surface 313 of a corresponding one of the first bonding pads 311. In other words, the connecting units 33 may be formed by wire-bonding techniques.

Step S4: forming an insulating package 7 to encapsulate the top circuit pattern layer 31, the image-sensing element 4, the light-emitting elements 5, the conductive elements 32, and the connecting units 33. As illustrated in FIG. 13, in certain embodiments, Step S4 may include sub-Steps S41 and S42.

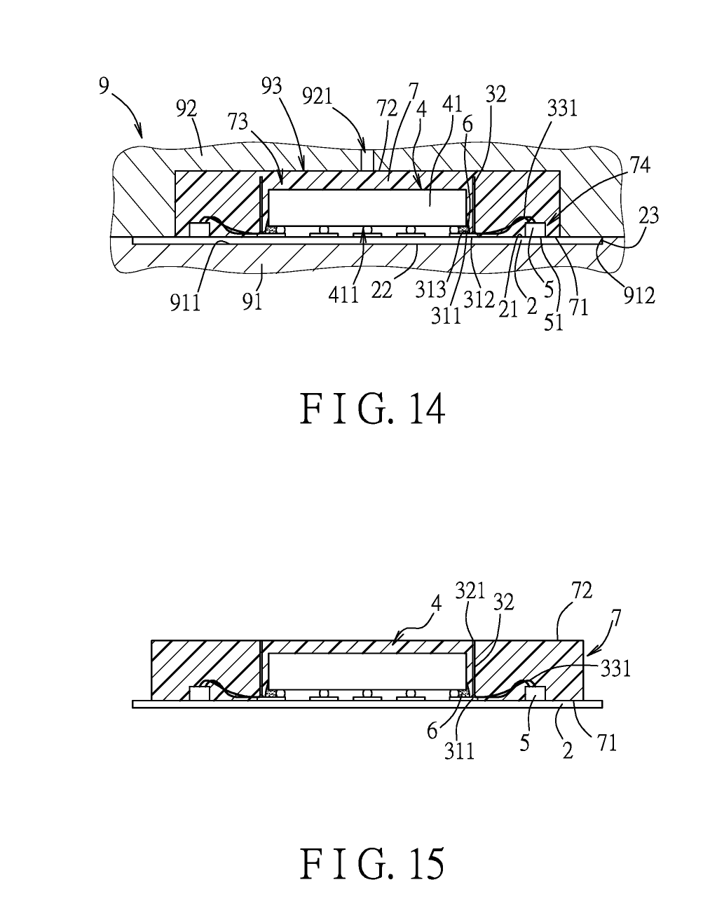

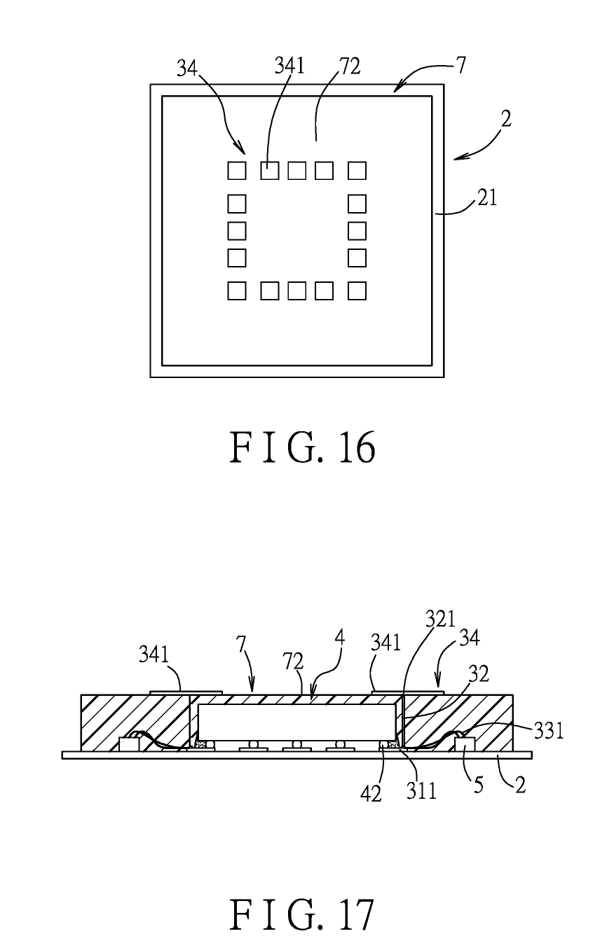

sub-Step S41: placing the supporting component 20 on a bottom die 91 of a mold 9 after Step S3, where a bottom surface 22 of the positioning element 2, which is opposite to the positioning surface 21, abuts against a bottom positioning surface 911 of the bottom die 91, and an outer surrounding surface 23 of the positioning element 2 abuts against a positioning surrounding surface 912 of the bottom die 91 as illustrated in FIG. 14. Thereafter, the bottom die 91 is combined with a top die 92 to form a mold cavity 93 receiving the supporting component 20, after which a molding material (not shown) is injected into the mold cavity 93 through a sprue 921 of the top die 92 to fill the mold cavity 93, so as to form the insulating package 7 which encapsulates the first bonding pads 311 of the top circuit pattern layer 31, the conductive elements 32, the connecting wires 331 of the connecting unit 33, the image-sensing die 41 of the image-sensing element 4 and the light-emitting elements 5. Since the outer end surface 312 of each of the first bonding pads 311 and the outer surface 51 of each of the light-emitting elements 5 are attached to the positioning surface 21 and since the image-sensing element 4 is connected to the first bonding pads 311, the relative position of the top circuit pattern layer 31, the image-sensing die 41 and the light-emitting elements 5 would not be affected during the injection of the molding material. It may be noted that, owing to the insulating adhesive 6 which fully isolates the light-emitting elements 5 from the external environment, the molding material is prevented from coming into contact with the sensing region 412 of the image-sensing die 41.

The insulating package 7 thus formed has a top surface 71 that is connected to the positioning surface 21 of the positioning element 2, and a bottom surface 72 that is opposite to the top surface 71 and that is formed with a first recess 73 receiving the image-sensing element 4, and a plurality of second recesses 74 each receiving a respective one of the light-emitting elements 5. It may be noted that, in certain embodiments, the insulating package 7 may completely encapsulate the conductive elements 32 and the connecting wires 331 as illustrated in FIG. 14.

sub-Step S42: grinding the bottom surface 72 of the insulating package 7, such that an inner end surface 321 of each of the conductive elements 32 is exposed from and coplanar with the bottom surface 72 of the insulating package 7 as illustrated in FIG. 15. Step S42 may be conducted using a grinding machine (not shown) to reduce the overall thickness of the insulating package 7.

Step S5: forming a bottom circuit pattern layer 34 on the bottom surface 72 of the insulating package 7 as illustrated in FIG. 17. In certain embodiments, the bottom circuit pattern layer 34 may be a redistribution layer (RDL) having a plurality of second bonding pads 341 each being electrically connected to the inner end surface 321 of a corresponding one of the conductive elements 32.

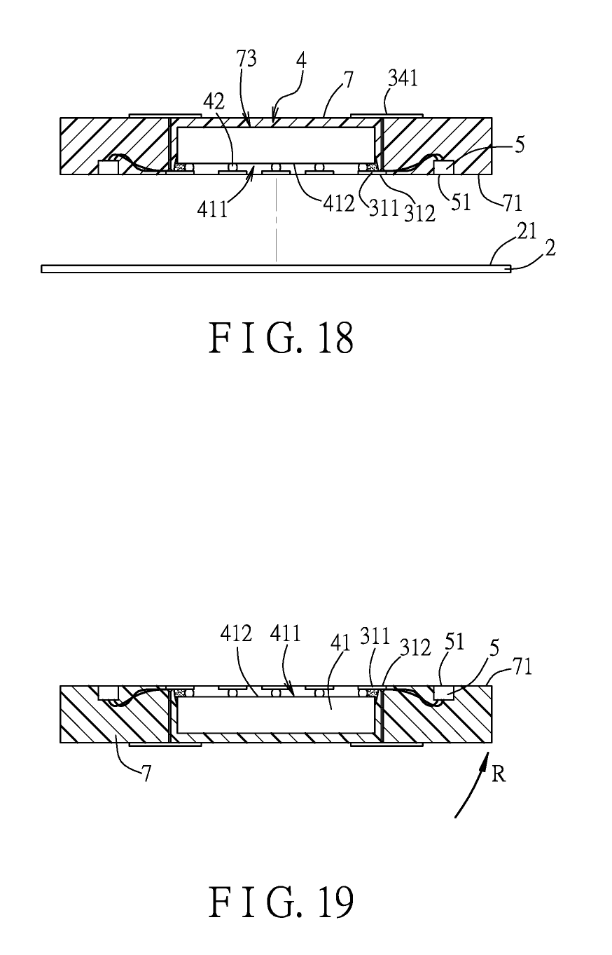

Step S6: removing the positioning element 2 from the insulating package 7, so as to expose the outer end surface 312 of the first bonding pads 311, the sensing region 412 of the outer surface 411 of the image-sensing die 41, and the outer surface 51 of each of the light-emitting elements 5 from the top surface 71 of the insulating package 7 as illustrated in FIG. 18. Since the conductive bumps 42 have a height relative to the first bonding pads 311, there is slight deviation in terms of distance between the top surface 71 of the insulating package 7 and the sensing region 412 of the image-sensing die 41.

Step S7: rotating the insulating package 7 in such a manner that the top surface 71 faces upward. In certain embodiments where the bottom surface 72 of the insulating package 7 originally faces upward, the insulating package 7 may be rotated 180° along a rotating direction (R) as illustrated in FIG. 19, such that the top surface 71 of the insulating package 7, the outer end surface 312 of each of the first bonding pads 311, the outer surface 411 of the image-sensing die 41, and the outer surface 51 of each of the light-emitting elements 5 face upward.

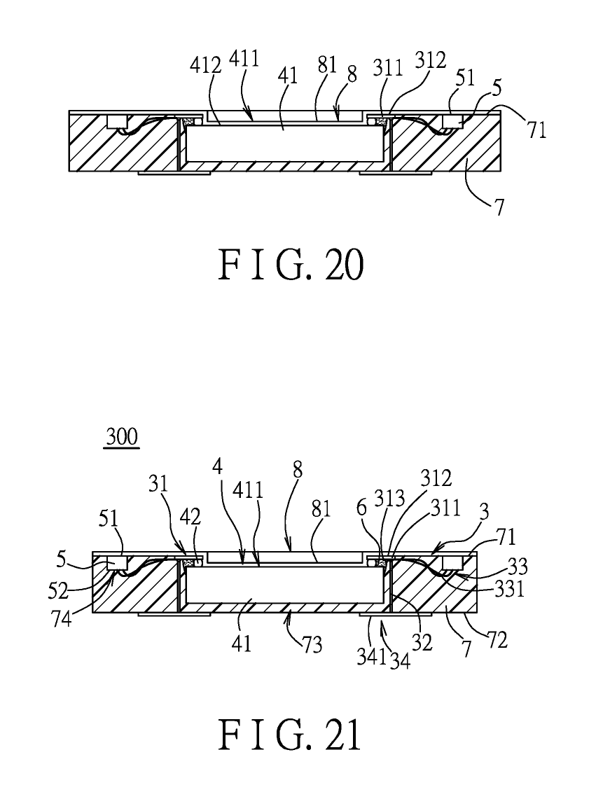

Step S8: forming a light-transmissive protecting layer 8 to cover the top surface 71 of the insulating package 7, the outer end surface 312 of each of the first bonding pads 311, the sensing region 412 of the outer surface 411 of the image-sensing die 41, and the outer surface 51 of each of the light-emitting elements 5 as illustrated in FIG. 20. The light-transmissive protecting layer 8 may have a contact plane 81 that is opposite to the insulating package 7 for finger contact of a user.

Step S9: cutting off lateral portions of the insulating package 7 and lateral portions of the light-transmissive protecting layer 8 by, for example, a cutting machine (not shown), so as to obtain the fingerprint sensing device 300 of the first exemplary embodiment as illustrated in FIG. 21. The fingerprint sensing device 300 of the first exemplary embodiment according to the present disclosure includes a conductive component 3 having opposite ends, i.e., the top and bottom circuit pattern layers 31, 34, correspondingly exposed from the top and bottom surfaces 71, 72 of the insulating package 7. In addition, the conductive component 3 of the first exemplary embodiment further includes the conductive elements 32 and the connecting units 33 as illustrated in FIG. 21.

The fingerprint sensing device 300 of the present disclosure has the following advantages:

(1) The utilization of the insulating package 7 to encapsulate the image-sensing die 41 and the light-emitting elements 5 allows the prism of the conventional fingerprint sensing devices to be omitted. For this reason, the fingerprint sensing device 300 of the present disclosure may be more compact in size and reduced in thickness, and thus can be applied to a wider range of electronic products, including wearable or handheld devices.

(2) The conductive elements 32 are configured as slim metal wires, so that the size of the fingerprint sensing device 300 can be further reduced.

(3) Since the first bonding pads 311 of the top circuit pattern layer 31 are positioned onto the positioning surface 21 of the positioning element 2, the conductive bumps 32 can be quickly, precisely and effectively connected to the first bonding pads 311.

(4) Since the sensing region 412 of the image-sensing die 41 is exposed from the top surface 71 of the insulating package 7, a distance between the contact plane 81 of the light-transmissive protecting layer 8 and the sensing region 412 of the image-sensing die 41 can be effectively reduced, so that the fingerprint sensing device 300 may have enhanced sensitivity.

(5) The method for producing the fingerprint sensing device 300 is relatively simple, and thus allows for reduced production costs and production time.

(6) By incorporating the conductive component 3 into the fingerprint sensing device 300, a circuit substrate required by the conventional fingerprint sensing devices can be omitted. As such, the overall thickness of the fingerprint sensing device 300 can be further reduced. Moreover, the internal stress problems caused by the difference between thermal expansion coefficients of the image-sensing die 41 and the circuit substrate can be prevented, resulting in relatively high product reliability.

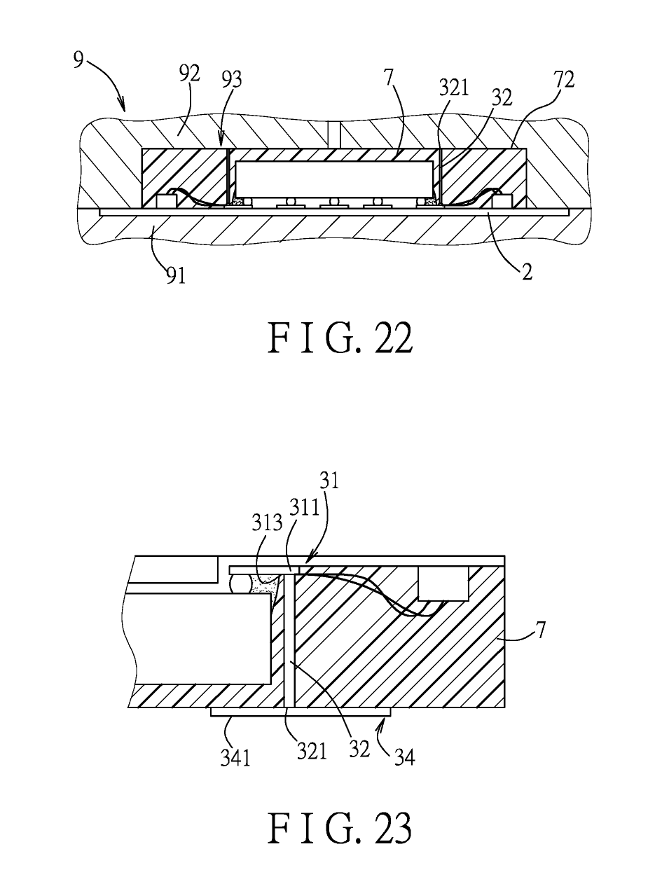

Referring to FIG. 22, the second exemplary embodiment of the fingerprint sensing device 300 and the method for producing the same are similar to those of the first exemplary embodiment, with the difference residing in that sub-Step S42 is omitted in the second exemplary embodiment. As illustrated in FIG. 22, during sub-Step S41 of the second exemplary embodiment, the inner end surface 321 of each of the conductive elements 32 abuts against the top die 92, such that the inner end surface 321 of each of the conductive elements 32 may be exposed directly after the forming of the insulating package 7 without having to grind the bottom surface 72 of the insulating package 7. In certain embodiments, the amount of the molding material to be injected into the mold cavity 93 may be controlled, so that the inner end surface 321 of each of the conductive elements 32 would not have to be submerged by the molding material during sub-Step 41, allowing the same to be directly exposed from the bottom surface 72 of the insulating package 7.

Referring to FIG. 23, the third exemplary embodiment of the fingerprint sensing device 300 and the method for producing the same according to the present disclosure are similar to those of the first exemplary embodiment, with the difference residing in that the conductive elements 32 of the third exemplary embodiment are configured as metal rods which may be formed on the connecting surface 313 of each of the first bonding pads 311 by, e.g., electroplating.

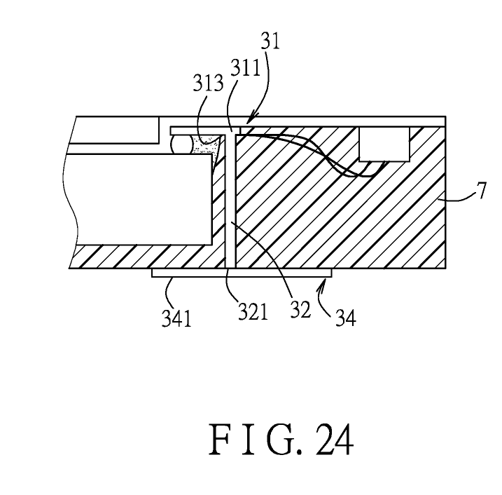

Referring to FIG. 24, the fourth exemplary embodiment of the fingerprint sensing device 300 and the method for producing the same according to the present disclosure are similar to those of the first exemplary embodiment, with the difference residing as follows.

In the fourth exemplary embodiment, each of the conductive elements 32 and the corresponding one of the first bonding pads 311 are integrally formed as one piece. For instance, each of the conductive elements 32 may be formed by bending a tip portion of the corresponding one of the first bonding pads 311 as illustrated in FIG. 24, so that the forming of the conductive elements 32 using the wire bonding machine in Step S3 of the first exemplary embodiment may be omitted.

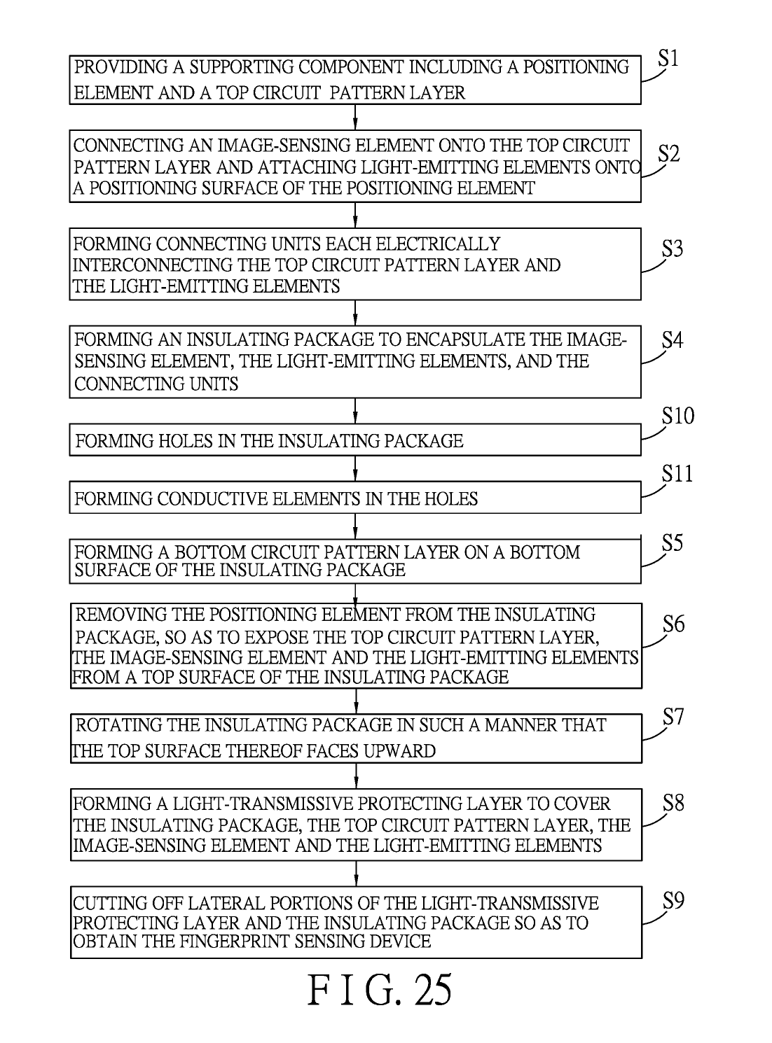

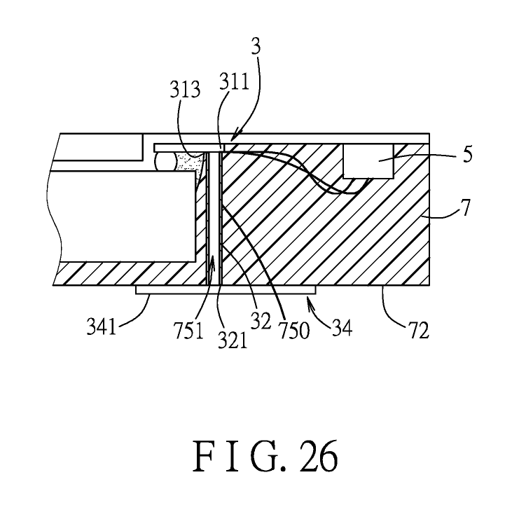

Referring to FIGS. 25 and 26, the fifth exemplary embodiment of the fingerprint sensing device 300 and the method for producing the same are similar to those of the first exemplary embodiment, with the difference residing in the configuration of the conductive elements 32.

In the fifth exemplary embodiment, the forming of the conductive elements 32 in Step S3 is omitted, and the method further includes a Step S10 of forming a plurality of holes 751 in the insulating package 7 to expose the connecting surfaces 313 of the first bonding pads 311, and a step S11 of forming the conductive elements 32 respectively in the holes 751. As illustrated in FIG. 26, each of the holes 751 extends from the connecting surface 313 of a respective one of the first bonding pads 311 to the bottom surface 72 of the insulating package 7 and is defined by a surrounding surface 750. Each of the conductive elements 32 is configured as a surrounding metal layer formed on the surrounding surface 750 in a respective one of the holes 751, so as to be in electrical contact with the respective one of the first bonding pads 311 and a respective one of the second bonding pads 341. Step S10, i.e., the forming of the holes 751, may be performed by laser drilling, and Step S11, i.e., the forming of the conductive elements 32, may be conducted by electroplating.

In summary, the utilization of the insulating package 7 to encapsulate the image-sensing die 41 and the light-emitting elements 5 allows the prism of the conventional fingerprint sensing devices to be omitted. For this reason, the fingerprint sensing device 300 of the present disclosure may be more compact in size and reduced in thickness, and thus can be applied to a wider range of electronic products, including wearable or handheld devices. In addition, since the first bonding pads 311 of the top circuit pattern layer 31 are positioned onto the positioning surface 21 of the positioning element 2, the conductive bumps 42 can be quickly, precisely and effectively connected to the first bonding pads 311. Moreover, since the sensing region 412 of the image-sensing die 41 is exposed from the top surface 71 of the insulating package 7, a distance between the contact plane 81 of the light-transmissive protecting layer 8 and the sensing region 412 of the image-sensing die 41 can be effectively reduced, so that the fingerprint sensing device 300 may have enhanced sensitivity. Furthermore, the method for producing the fingerprint sensing device 300 is relatively simple, and thus allows for reduced production costs and production time. Even further, by incorporating the conductive component 3 into the fingerprint sensing device 300, a circuit substrate required by the conventional fingerprint sensing device can be omitted. As such, the overall thickness of the fingerprint sensing device 300 can be further reduced. In addition, the internal stress problems caused by the difference between thermal expansion coefficients of the image-sensing die 41 and the circuit substrate can be prevented, resulting in relatively high product reliability.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A fingerprint sensing device, comprising:
an insulating package having
a top surface that is formed with a first recess and a second recess, and
a bottom surface that is opposite to said top surface;
a conductive component formed in said insulating package and having opposite top and bottom ends that are respectively exposed from said top and bottom surfaces of said insulating package;
an image-sensing element electrically connected to said conductive component by flip-chip techniques, disposed in said first recess, and having a sensing region that is exposed from said first recess; and
a light-emitting element disposed in said second recess and electrically coupled to said conductive component.

2. The fingerprint sensing device according to claim 1, wherein said conductive component includes a top circuit pattern layer that has said top end of said conductive component, that is formed on said top surface of said insulating package and that is electrically coupled to said image-sensing element.

3. The fingerprint sensing device according to claim 2, wherein:
said top circuit pattern layer includes a plurality of mutually spaced-apart first bonding pads, each having an outer end surface that is exposed from said top surface of said insulating package, and a connecting surface that is opposite to said outer end surface; and
said image-sensing element includes a plurality of conductive bumps each being connected to said connecting surface of a corresponding one of said first bonding pads.

4. The fingerprint sensing device according to claim 3, wherein:
said image-sensing element further includes an image-sensing die having a top surface, said top surface including
said sensing region, and
a connecting region surrounding said sensing region and provided with said conductive bumps; and
the fingerprint sensing device further comprises an insulating adhesive that is formed along an outer periphery of said image-sensing die, that is filled between said connecting region and said first bonding pads, and that encloses said conductive bumps.

5. The fingerprint sensing device according to claim 3, wherein:
said light-emitting element is an LED having an inner surface facing toward said bottom surface of said insulating package, and an electrode unit disposed on said inner surface; and
said conductive component further includes a connecting unit electrically interconnecting said electrode unit and said connecting surface of said first bonding pads.

6. The fingerprint sensing device according to claim 5, wherein said light-emitting element further has an outer surface that is coplanar with said outer end surface of each of said first bonding pads and said top surface of said insulating package.

7. The fingerprint sensing device according to claim 3, wherein said conductive component further includes a plurality of conductive elements each being electrically coupled to said connecting surface of a corresponding one of said first bonding pads and having an inner end surface that is exposed from and coplanar with said bottom surface of said insulating package.

8. The fingerprint sensing device according to claim 7, wherein said conductive component further includes a bottom circuit pattern layer that has said bottom end of said conductive component, that is formed on said bottom surface of said insulating package, and that includes a plurality of mutually spaced-apart second bonding pads each being electrically coupled to said inner end surface of a corresponding one of said conductive elements.

9. The fingerprint sensing device according to claim 7, wherein said conductive elements are configured as metal wires.

10. The fingerprint sensing device according to claim 7, wherein said conductive elements are configured as metal rods.

11. The fingerprint sensing device according to claim 7, wherein each of said conductive elements and the corresponding one of said first bonding pads are integrally formed as one piece.

12. The fingerprint sensing device according to claim 7, wherein:
said insulating package is formed with a plurality of holes each extending from said connecting surface of the respective one of said first bonding pads to said bottom surface and each being defined by a surrounding surface; and
each of said conductive elements is configured as a surrounding metal layer formed on said surrounding surface in a respective one of said holes.

13. A method for producing a fingerprint sensing device, comprising the steps of:
providing a supporting component which includes a positioning element having a positioning surface, and a top circuit pattern layer positioned on the positioning surface;
connecting an image-sensing element onto the top circuit pattern layer such that the image-sensing element is electrically coupled to the top circuit pattern layer, followed by attaching a light-emitting element onto the positioning surface;
forming a plurality of conductive elements each being electrically coupled to the top circuit pattern layer, and forming a connecting unit electrically interconnecting the top circuit pattern layer and the light-emitting element;
forming an insulating package to encapsulate the top circuit pattern layer, the image-sensing element, the conductive elements and the connecting unit, wherein the insulating package has a top surface connected to the positioning surface of the positioning element and a bottom surface opposite to the top surface; and
removing the positioning element from the insulating package so as to expose the top circuit pattern layer, the image-sensing element and the light-emitting element from the top surface of the insulating package.

14. The method of claim 13, wherein the step of connecting the image-sensing element onto the top circuit pattern layer is performed by flip-chip techniques.

15. The method of claim 14, wherein:
the image-sensing element includes
an image-sensing die having an outer surface which has a sensing region and a connecting region surrounding the sensing region, and
a plurality of conductive bumps disposed on the connecting region;
the top circuit pattern layer includes a plurality of mutually spaced-apart first bonding pads each having a connecting surface;
the step of connecting the image-sensing element onto the top circuit pattern layer includes connecting the conductive bumps correspondingly onto the connecting surface of the first bonding pads by soldering; and
the method further comprises, prior to the step of forming the insulating package, a step of applying an insulating adhesive along an outer periphery of the image-sensing die to fill a gap between the connecting region and the first bonding pads and to enclose the conductive bumps.

16. The method of claim 15, wherein:
the light-emitting element has an outer surface that is connected to the positioning surface of the positioning element, and each of the first bonding pads has an outer end surface that is opposite to the connecting surface and that is connected to the positioning surface of the positioning element; and
in the step of removing the positioning element, the outer surface of the light-emitting element and the outer end surface of each of the first bonding pads are exposed from and coplanar with the top surface of the insulating package.

17. The method of claim 15, wherein:
the light-emitting element is a sapphire-based LED and further has
an inner surface that is opposite to the outer surface, and an electrode unit that is disposed on the inner surface; and
the method further comprises a step of electrically connecting the electrode unit to the connecting surface of a corresponding one of the first bonding pads by wire bonding.

18. The method of claim 15, wherein each of the conductive elements is configured as a metal wire formed by a wire-bonding machine.

19. The method of claim 15, wherein each of the conductive elements is configured as a metal rod formed by electroplating.

20. The method of claim 15, wherein each of the conductive elements and the corresponding one of the first bonding pads are integrally formed as one piece.

21. The method of claim 13, further comprising a step of forming a light-transmissive protecting layer to cover the top surface of the insulating package, the top circuit pattern layer, the image-sensing element, and the light-emitting element.

22. The method of claim 21, further comprising, prior to the step of forming the light-transmissive protecting layer, a step of rotating the insulating package in such a manner that the top surface faces upward.

23. The method of claim 13, wherein:
each of the conductive elements has an inner end surface that is exposed from and coplanar with the bottom surface of the insulating package; and
the method further comprises a step of forming a bottom circuit pattern layer on the bottom surface of the insulating package such that the bottom circuit pattern layer has a plurality of second bonding pads each being electrically coupled to the inner end surface of a corresponding one of the conductive elements.

24. The method of claim 23, further comprising a step of grinding the bottom surface of the insulating package such that the inner end surface of each of the conductive elements is exposed from and coplanar with the bottom surface of the insulating package.

25. The method of claim 13, wherein the positioning element is a tape, and the positioning surface is an adhesive plane.

26. A method for producing a fingerprint sensing device, comprising steps of:
providing a supporting component which includes a positioning element having a positioning surface, and a top circuit pattern layer positioned on the positioning surface;
connecting an image-sensing element onto the top circuit pattern layer such that the image-sensing element is electrically connected to the top circuit pattern layer, followed by attaching a light-emitting element onto the positioning surface;
forming a connecting unit to electrically interconnect the top circuit pattern layer and the light-emitting element;
forming an insulating package to encapsulate the top circuit pattern layer, the image-sensing element, and the connecting unit, wherein the insulating package has a top surface connected to the positioning surface of the positioning element, and a bottom surface opposite to the top surface;
forming a plurality of holes each extending from the bottom surface of the insulating package to the top circuit pattern layer and each being defined by a surrounding surface;
forming conductive elements respectively in the holes such that the conductive elements are electrically coupled to the top circuit pattern layer, wherein each of the conductive elements is formed on the surrounding surface in a respective one of the holes by electroplating; and
removing the positioning element from the insulating package so as to expose the top circuit pattern layer, the image-sensing element and the light-emitting element from the top surface of the insulating package.
